(19) United States
(12) Patent Application Publication
(10) Pub. No.: US 2019/0311887 A1
(43) Pub. Date: Oct. 10, 2019

(54) MULTIZONE GAS DISTRIBUTION APPARATUS

(71) Applicant: Applied Materials, Inc., Santa Clara, CA (US)

(72) Inventors: Akshay GUNAJI, Bengaluru (IN); Tuan Anh NGUYEN, San Jose, CA (US); Mayur G. KULKARNI, Bangalore (IN); Sanjeev BALUJA, Campbell, CA (US); Kurt LANGELAND, San Jose, CA (US)

(21) Appl. No.: 16/369,911

(22) Filed: Mar. 29, 2019

(30) Foreign Application Priority Data
Apr. 6, 2018 (IN) 201841013167

(51) Int. Cl. H01J 37/32; C23C 16/455

(52) U.S. Cl. CPC H01J 37/32449; C23C 16/45512; H01J 2237/3321; H01J 2237/186; H01J 37/32357

(57) ABSTRACT

The present disclosure relates to a fluid delivery system assembly for use with a semiconductor process chamber. A series of three-way valves control process fluid flow between process fluid conduits which lead to the process chamber and a divert conduit.

### CROSS-REFERENCE TO RELATED APPLICATIONS

This application claims benefit of Indian Provisional Patent Application 201841013167 filed on Apr. 6, 2018 at the Indian Patent Office, which is herein incorporated by reference.

### BACKGROUND

### Field

The present disclosure relates to a fluid delivery system for use with a semiconductor process chamber.

### Description of the Related Art

In the fabrication of integrated circuits, deposition processes, such as chemical vapor deposition (CVD), are often used to deposit films of various materials on substrates. In plasma-enhanced chemical vapor deposition (PECVD), for instance, electromagnetic energy is applied to at least one precursor gas or vapor to generate a plasma.

The various process fluids, such as gases or the like, used to perform deposition processes are routed through mixing assemblies before being introduced into a process chamber so that the flows and mixtures of the process fluids can be precisely controlled. Conventional mixing assemblies often include both process fluid conduits, which deliver the process fluids to the process chamber, and divert conduits, which are used to regulate the flow of the process fluids, particularly toxic precursors such as silane and tetraethoxysilane (TEOS), by diverting the process fluids from the process chamber when necessary. In conventional mixing assembly designs, a combination of two- and three-way valves control the flow of process fluids between the process fluid conduits and divert conduits. A three-way valve in an open position enables fluid flow into the process fluid conduit and subsequently to the process chamber. A two-way valve between the three-way valve and a divert conduit in an open position enables fluid flow into the divert conduit.

Hence, when fluid flow is to be diverted from the process chamber to the divert conduit, the three-way valve is first closed, and then the two-way valve is opened. The time delay between the closing of the three-way valve and the opening of the two-way valve can reduce overall throughput. Additionally, the delay allows for the buildup of process fluid in dead space between the valves, which can cause undesirable particle generation in the dead space. Mixing assembly cleaning and/or purging is utilized to remove particles and may increase tool down time as a result thereof. Moreover, the presence of particles in the mixing assembly increases the probability of particles being delivered to the process chamber during substrate processing, which may result in undesirable particle deposition on the substrate.

Accordingly, what is needed in the art are improved apparatus for fluid mixing.

### SUMMARY

In one embodiment, a fluid delivery system is provided. The system includes a process fluid conduit and a divert conduit. The system further includes a first three-way valve coupled to a first conduit and a second conduit. The first conduit is coupled to the process fluid conduit and the second conduit is coupled to the divert conduit. The system further includes a second three-way valve coupled to a third conduit and a fourth conduit. The third conduit is coupled to the process fluid conduit and the fourth conduit is coupled to the divert conduit. The system further includes a third three-way valve coupled to a fifth conduit and a sixth conduit. The fifth conduit is coupled to the process fluid conduit and the sixth conduit is coupled to the divert conduit. The system further includes a purge gas valve coupled to a seventh conduit. The seventh conduit is coupled to the process fluid conduit.

In another embodiment, a fluid delivery system is provided. The system includes a first process fluid conduit, a second process fluid conduit, and a divert conduit. The system further includes a first three-way valve coupled to a first conduit and a second conduit. The first conduit is coupled to the first process fluid conduit and the second conduit is coupled to the divert conduit. The system further includes a second three-way valve coupled to a third conduit and a fourth conduit. The third conduit is coupled to the first process fluid conduit and the fourth conduit is coupled to the divert conduit. The system further includes a third three-way valve coupled to a fifth conduit and a sixth conduit. The fifth conduit is coupled to the first process fluid conduit and the sixth conduit is coupled to the divert conduit. The system further includes a fourth three-way valve coupled to the second process fluid conduit and the divert conduit. The system further includes a purge gas valve coupled to a seventh conduit. The seventh conduit is coupled to the process fluid conduit.

In another embodiment, an apparatus for processing a semiconductor substrate is provided. The apparatus includes a chamber defining a process volume, a substrate support disposed in the process volume, and a lid assembly coupled to the chamber opposite the substrate support. The apparatus further includes a first process fluid conduit disposed through the lid assembly and in fluid communication with the process volume, a second process fluid conduit disposed through the lid assembly and in fluid communication with the process volume, and a divert conduit. The apparatus further includes a first three-way valve coupled to a first conduit and a second conduit. The first conduit is coupled to the first process fluid conduit and the second conduit is coupled to the divert conduit. The apparatus further includes a second three-way valve coupled to a third conduit and a fourth conduit. The third conduit is coupled to the first process fluid conduit and the fourth conduit is coupled to the divert conduit. The apparatus further includes a third three-way valve coupled to a fifth conduit and a sixth conduit. The fifth conduit is coupled to the first process fluid conduit and the sixth conduit is coupled to the divert conduit. The apparatus further includes a fourth three-way valve coupled to the second process fluid conduit and the divert conduit. The apparatus further includes a purge gas valve coupled to a seventh conduit. The seventh conduit is coupled to the process fluid conduit.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 illustrates a schematic view of a fluid delivery system according to an embodiment described herein.

FIG. 2 illustrates a schematic view of a process chamber according to an embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a fluid delivery system for use with a semiconductor process chamber. A series of three-way valves control process fluid flow between process fluid conduits which lead to the process chamber and a divert conduit. The use of the three-way valves eliminates dead spaces in the fluid delivery system, preventing particle generation when process fluids are caught in the dead spaces. The use of a single three-way valve to regulate flow of each fluid also reduces time delays caused by valve sequencing. Additionally, embodiments of the disclosure also allow for tuning radial uniformity of deposition processes, by allowing for the modulation of fluid flow to separate regions of the chamber.

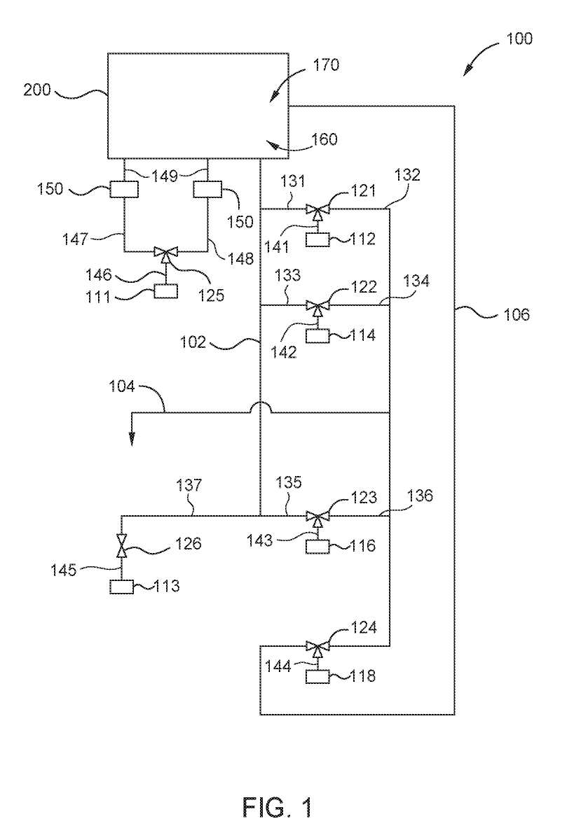

FIG. 1 illustrates a system having a process chamber 200 coupled to a fluid delivery system 100 according to one embodiment. The fluid delivery system 100 includes a plurality of valves 121, 122, 123, 124, 125, and 126 and a plurality of conduits, such as conduits 102, 106, 131, 132, 133, 134, 135, 136, 137, 141, 142, 143, 144, 145, 146, 147, 148, and 149, to route process gases from process gas sources, such as process fluid sources 112, 114, 116, and 118, of the fluid delivery system 100 to the process chamber 200.

A first process fluid conduit 102 carries process fluids from the fluid delivery system 100 to a process chamber 200. The first process fluid conduit 102 is composed of suitable metallic materials. In one embodiment, the first process fluid conduit 102 is formed from an aluminum or stainless steel material. The first process fluid conduit 102 enables a plurality of process fluids to mix before the process fluids are introduced into the process chamber 200.

The fluid delivery system 100 is in fluid communication with one or more fluid sources which provide the process fluids used to perform deposition or other processes in the chamber 200. A first process fluid source 112 is coupled to and in fluid communication with a process fluid source conduit 141. In one embodiment, the first process fluid source 112 provides a silicon precursor such as silane or tetraethoxysilane (TEOS). In other embodiments, the first process fluid source 112 provides any fluid that is commonly used in semiconductor processing. The process fluid source conduit 141 is coupled to and in fluid communication with a first three-way valve 121 and configured to deliver process fluid from the first process fluid source 112 to the fluid delivery system 100. In one embodiment, the first three-way valve 121 is a pneumatic three-way valve. A conduit 131 is coupled to the first three-way valve 121. The conduit 131 is also coupled to and in fluid communication with the first process fluid conduit 102, facilitating delivery of a process fluid from the first process fluid source 112 to the process chamber 200.

A conduit 132 is coupled to the three-way valve 121 opposite the conduit 131 and the conduit 132 is coupled to and in fluid communication with a divert conduit 104. The divert conduit 104 regulates fluid flow by providing an outlet for process fluids when the process fluids are not sent to the process chamber 200. Fluid flow is switched between the conduit 131, leading to the first process fluid conduit 102 and the process chamber 200, and the conduit 132, leading to the divert conduit 104, by actuation of the first three-way valve 121. For example, when the first three-way valve 121 is in an open position, fluid flows from the first process fluid source 112 through the first three-way valve 121 and the conduit 131 to the first process fluid conduit 102 and the process chamber 200. When the first three-way valve 121 is in a divert position, fluid flows from the first process fluid source 112 through the first three-way valve 121 and the conduit 132 to the divert conduit 104 away from the process chamber 200. When the first three-way valve 121 is in a closed position, the first three-way valve 121 prevents fluid flow from the first process fluid source 112 to either of the conduit 131 and the first process fluid conduit 102 or the conduit 132 and the divert conduit 104, respectively.

A second process fluid source 114 is coupled to and in fluid communication with a process fluid source conduit 142. In one embodiment, the second process fluid source 114 provides a silicon precursor, such as silane or TEOS, to the fluid delivery system 100. In other embodiments, the second process fluid source 114 provides any fluid that is commonly used in semiconductor processing. In another embodiment, the second process fluid source 114 and the first process fluid source 112 provide different process fluids. The process fluid source conduit 142 is coupled to a second three-way valve 122 and configured to deliver process fluid from the second process fluid source 114 to the fluid delivery system 100. A conduit 133 is coupled to the second three-way valve 122 and the conduit 133 is coupled to and in fluid communication with the first process fluid conduit 102. A conduit 134 is coupled to the second three-way valve 122 opposite the conduit 133 and the conduit 134 is coupled to and in fluid communication with the divert conduit 104. Similar to the first three-way valve 121, the second three-way valve 122 enables process fluid to be sent to either the first process fluid conduit 102 or the divert conduit 104 by actuation of the second three-way valve 122.

A third process fluid source 116 is coupled to and in fluid communication with a process fluid source conduit 143. In one embodiment, the third process fluid source 116 provides an oxygen containing precursor, such as oxygen gas (e.g., O₂) or nitrous oxide (e.g., N₂O), to the fluid delivery system 100. In other embodiments, the third process fluid source 116 provides any fluid that is commonly used in semiconductor processing. The process fluid source conduit 143 is coupled to a third three-way valve 123 and configured to deliver process fluid to the fluid delivery system 100. A conduit 135 is coupled to the third three-way valve 123 and the conduit 135 is coupled to and in fluid communication with the first process fluid conduit 102. A conduit 136 is coupled to the third three-way valve 123 opposite the conduit 135 and the conduit 136 is coupled to and in fluid communication with the divert conduit 104. Similar to the first three-way valve 121 and the second three-way valve 122, the third three-way valve 123 enables process fluid to be sent to either the first process fluid conduit 102 or the divert conduit 104 by actuation of the third three-way valve 123.

A purge gas conduit 145 is coupled to and in fluid communication with a purge gas source 113. In one embodiment, the purge gas source 113 provides an inert gas, such as argon, to the fluid delivery system 100. The purge gas conduit 145 is coupled to a valve 126. The valve 126 is illustrated in FIG. 1 as a two-way valve. However, it is contemplated that other suitable valve designs may be used. A conduit 137 is coupled to the valve 126 and the conduit 137 extends between the valve 126 and the first process fluid conduit 102.

The conduit 131 is coupled to the first process fluid conduit 102 adjacent to the process chamber 200. The conduit 133 is coupled to the first process fluid conduit 102 upstream of the conduit 131 such that the conduit 131 is coupled to the first process fluid conduit 102 between the process chamber 200 and the conduit 133. The conduit 135 is coupled to the first process fluid conduit 102 upstream of the conduit 133 such that the conduit 133 is coupled to the first process fluid conduit 102 between the conduit 131 and the conduit 135. The conduit 137 is coupled to the first process fluid conduit 102 upstream of the conduit 135 such that the conduit 135 is coupled to the first process fluid conduit 102 between the conduit 133 and the conduit 137. Thus, a purge gas can thus be introduced upstream of the three-way valves 121, 122, and 123 so that excess process fluids and particle build-up can be purged from the fluid delivery system 100, and more specifically, the first process fluid conduit 102.

In one embodiment, a conduit 144 is coupled to and in fluid communication with a fourth process fluid source 118. In one embodiment, the fourth process fluid source 118 provides a silicon precursor such as silane or TEOS to the fluid delivery system 100. In another embodiment, the fourth process fluid source 118 provides the same process fluid to the fluid delivery system 100 as either the first process fluid source 112 or the second process fluid source 114. The conduit 144 is coupled to a fourth three-way valve 124 and configured to deliver process fluid from the fourth process fluid source 118 through the fourth three-way valve 124 to the fluid delivery system 100.

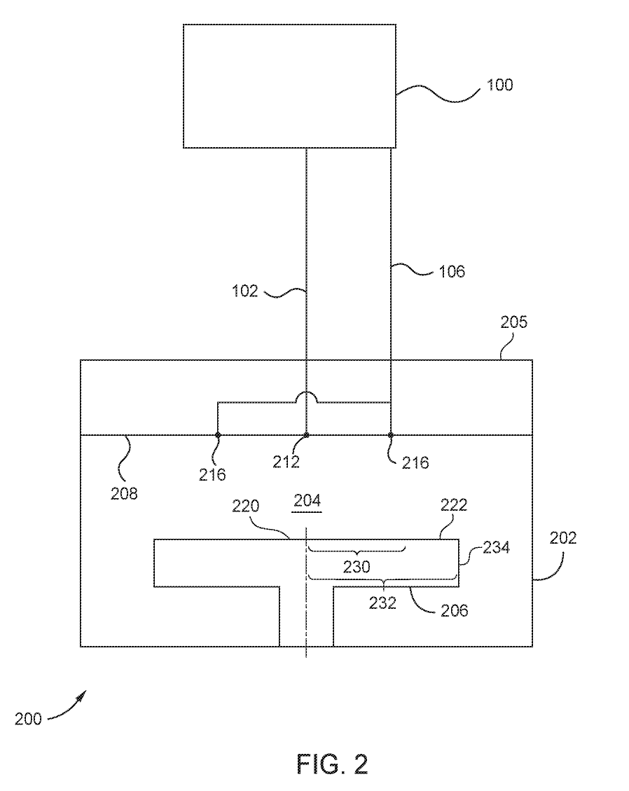

The fourth three-way valve 124 is coupled to the divert conduit 104 and to a second process fluid conduit 106. The fourth three-way valve 124 enables process fluid to be sent to either the second process fluid conduit 106 or the divert conduit 104 by actuation of the fourth three-way valve 124. For example, when the fourth three-way valve 124 is in a divert position, fluid from the fourth process fluid source 118 is directed to the divert conduit 104. When the fourth three-way valve 124 is in an open position, fluid from the fourth process fluid source 118 is directed to the process chamber 200 via the second process fluid conduit 106. The second process fluid conduit 106 enables process fluid to be sent to a first region 170 of the process chamber 200. In one embodiment, the first region 170 corresponds to a region of the process chamber 200 adjacent an edge of a substrate disposed in the process chamber 200. In contrast, the first process fluid conduit 102 enables process fluid to be sent to a second region 160 of the process chamber 200. In one embodiment, the second region 160 corresponds to a center region of a substrate disposed in the process chamber 200. In one embodiment, the second region 160 is radially inward of the first region 170 in the process chamber 200. Utilization of the second process fluid conduit 106 coupled to and in fluid communication with the process chamber 200 at the first region 170 provides for improved radial deposition uniformity control, as will be described in more detail with regard to FIG. 2.

In one embodiment, the fluid delivery system 100 includes remote plasma conduits 149. The remote plasma conduits 149 are coupled to remote plasma sources 150 and extend between the remote plasma sources 150 and the process chamber 200. The remote plasma sources 150 are also coupled to the conduits 147 and 148. The conduit 147 is coupled to a valve 125 opposite the conduit 148. Each of the conduits 147, 148 extend between the valve 125 and a respective plasma source 150. The valve 125 is coupled to a conduit 146 which is coupled to and in fluid communication with a plasma gas source 111. The plasma gas source 111 provides a gas, such as nitrogen trifluoride (NF₃), to the remote plasma sources 150 via the valve 125 and the conduits 146, 147, and 148.

FIG. 1 shows two remote plasma sources 150 and depicts the valve 125 as a three-way valve. However, it is contemplated that any suitable arrangement, type, and number of valves, conduits, and remote plasma sources may be utilized for introduction of plasma into the process chamber 200.

Embodiments of the present disclosure advantageously provide for the elimination of dead space in the fluid delivery system 100. The three-way valves 121, 122, 123, and 124 each enable the process fluid to be switched between the process fluid conduits 102 and 106 and the divert conduit 104 without the use of additional valves, e.g., using only a single valve for directing the process fluid to either the process chamber 200 or the divert conduit 104. Thus, dead space between the valves is eliminated to reduce the probability of particle generation in the dead space. As a result, a reduction in particle exposure to substrates during processing is achieved, which reduces the occurrence of defects during substrate processing.

Additionally, the three-way valves 121, 122, 123, and 124 provide for improved throughput. Process fluid from a particular source can be diverted by opening and closing and single valve as opposed to multiple valves, eliminating time delays caused by valve sequencing.

FIG. 2 illustrates a schematic view of the process chamber 200 according to one embodiment. A suitable, commercially available process chamber which may be advantageously employed in accordance with the embodiments described herein is the PRODUCER® PRECISION™ processing apparatus available from Applied Materials, Inc., Santa Clara, Calif. It is contemplated that other suitably configured process chambers from other manufacturers may also be utilized in accordance with the embodiments described herein.

The process chamber 200 includes a chamber body 202 defining a process volume 204. The chamber body 202 is formed from a metallic material, such as aluminum or stainless steel. However, it is contemplated that other materials suitable for use with sub-atmospheric processing therein may be utilized. A substrate support 206 is disposed in the process volume 204. A lid assembly 205 is coupled to the chamber body 202 opposite the substrate support 206.

The process chamber 200 is coupled to the fluid delivery system 100 by the first and second process fluid conduits 102 and 106, which are in fluid communication with the process volume 204. The first and second process fluid conduits 102 and 106 are disposed through the lid assembly 205. The first and second process fluid conduits 102 and 106 are coupled to and in fluid communication with fluid ports 212 and 216, respectively. The fluid ports 212 and 216 are formed in a surface 208 of the lid assembly 205. While a single fluid port 212 is coupled to and in fluid communication with the first process fluid conduit 102 and two fluid ports 216 are coupled to and in fluid communication with the second process fluid conduit 102 as shown in FIG. 2, it is contemplated that any suitable number and arrangement of fluid ports 212 and 216 may be formed into the surface 208 to facilitate distribution of process fluids into the process volume 204.

In one embodiment, the fluid ports 212 are arranged such that the first process fluid conduit 102 is configured to deliver process fluid to an area of the process volume 204 adjacent to a center region 220 of the substrate support 206. In one embodiment, the center region 220 of the substrate support 206 corresponds to the second region 160 illustrated in FIG. 1. The center region 220 is defined by a radius 230, which in one embodiment is about 90 mm. The fluid ports 216 are arranged such that the second process fluid conduit 106 is configured to deliver process fluid to an area of the process volume 204 adjacent to an outer region 222 of the substrate support. In one embodiment, the outer region 222 corresponds to the first region 170 illustrated in FIG. 1. The outer region 222 extends from the radius 230 to an outer edge 234 of the substrate support 206. The outer region is at least partially defined by an outer radius 232. In one embodiment, the outer radius 232 is about 150 mm.

Thus, the first and second process fluid conduits 102 and 106 and the three-way valves 121, 122, 123, 124 in the fluid delivery system 100 enable modulation of radial gas distribution during deposition processes. For example, to increase radial uniformity for a deposition process that tends to a center-high deposition profile, the first, second, and third three-way valves 121, 122, 123 can be selectively actuated to reduce process fluid flow to the center region 220. The reduction in process fluid flow to the center region 220 reduces the amount of material deposited in a center region of a substrate. The fourth three-way valve 124 can be actuated to increase process fluid flow to the outer region 222. The increased process fluid flow to the outer region increases the amount of material deposited near an edge of the substrate. In this manner, radial uniformity can be tuned according the characteristics of the process being performed.

Some embodiments described herein include four process fluid sources and respective three-way valves. However, it is contemplated that more any number of process fluid sources and respective three-way valves may be used to substantially reduce dead space in the fluid delivery system and substantially reduce time delays caused by valve sequencing.

While the foregoing is directed to embodiments of the present disclosure, other and further embodiments of the disclosure may be devised without departing from the basic scope thereof, and the scope thereof is determined by the claims that follow.

What is claimed is:

1. A fluid delivery assembly, comprising:
a process fluid conduit;
a divert conduit;
a first three-way valve coupled to a first conduit and a second conduit, wherein the first conduit is coupled to the process fluid conduit and the second conduit is coupled to the divert conduit;
a second three-way valve coupled to a third conduit and a fourth conduit, wherein the third conduit is coupled to the process fluid conduit and the fourth conduit is coupled to the divert conduit;
a third three-way valve coupled to a fifth conduit and a sixth conduit, wherein the fifth conduit is coupled to the process fluid conduit and the sixth conduit is coupled to the divert conduit; and
a purge gas valve coupled to a seventh conduit, wherein the seventh conduit is coupled to the process fluid conduit.

2. The fluid delivery assembly of claim 1, wherein the seventh conduit is coupled to the process fluid conduit upstream of the first, third, and fifth conduits.

3. The fluid delivery assembly of claim 1, wherein the first three-way valve is coupled to a process fluid source conduit configured to deliver a first process fluid, selected from the group consisting of silane and tetraethoxysilane, to the assembly.

4. The fluid delivery assembly of claim 3, wherein the second three-way valve is coupled to a second process fluid source conduit configured to deliver a second process fluid, selected from the group consisting of silane and tetraethoxysilane, to the assembly.

5. The fluid delivery assembly of claim 4, wherein the third three-way valve is coupled to a third process fluid source conduit configured to deliver a third process fluid, selected from the group consisting of oxygen gas and nitrous oxide, to the assembly.

6. The fluid delivery assembly of claim 5, wherein the first process fluid and the second process fluid are different.

7. A fluid delivery assembly, comprising:
a first process fluid conduit;
a second process fluid conduit;
a divert conduit;
a first three-way valve coupled to a first conduit and a second conduit, wherein the first conduit is coupled to the first process fluid conduit and the second conduit is coupled to the divert conduit;
a second three-way valve coupled to a third conduit and a fourth conduit, wherein the third conduit is coupled to the first process fluid conduit and the fourth conduit is coupled to the divert conduit;
a third three-way valve coupled to a fifth conduit and a sixth conduit, wherein the fifth conduit is coupled to the first process fluid conduit and the sixth conduit is coupled to the divert conduit;
a fourth three-way valve coupled to the second process fluid conduit and the divert conduit; and
a purge gas valve coupled to a seventh conduit, wherein the seventh conduit is coupled to the first process fluid conduit.

8. The fluid delivery assembly of claim 7, wherein the seventh conduit is coupled to the first process fluid conduit upstream of the first, third, and fifth conduits.

9. The fluid delivery assembly of claim 7, wherein the first three-way valve is coupled to a process fluid source conduit configured to deliver a first process fluid, selected from the group consisting of silane and tetraethoxysilane, to the assembly.

10. The fluid delivery assembly of claim 9, wherein the second three-way valve is coupled to a second process fluid source conduit configured to deliver a second process fluid, selected from the group consisting of silane and tetraethoxysilane, to the assembly.

11. The fluid delivery assembly of claim 10, wherein the third three-way valve is coupled to a third process fluid source conduit configured to deliver a third process fluid, selected from the group consisting of oxygen gas and nitrous oxide, to the assembly.

12. The fluid delivery assembly of claim 11, wherein the fourth three-way valve is coupled to a fourth process fluid source conduit configured to deliver a fourth process fluid, selected from the group consisting of silane and tetraethoxysilane, to the assembly.

13. The fluid delivery assembly of claim 12, wherein the first process fluid and the second process fluid are different and the fourth process fluid is the same as the first process fluid or second process fluid.

14. An apparatus for processing a semiconductor substrate, comprising:
a chamber defining a process volume;
a substrate support disposed in the process volume;
a lid assembly coupled to the chamber opposite the substrate support;
a first process fluid conduit disposed through the lid assembly and in fluid communication with the process volume;
a second process fluid conduit disposed through the lid assembly and in fluid communication with the process volume;
a divert conduit;
a first three-way valve coupled to a first conduit and a second conduit, wherein the first conduit is coupled to the first process fluid conduit and the second conduit is coupled to the divert conduit;
a second three-way valve coupled to a third conduit and a fourth conduit, wherein the third conduit is coupled to the first process fluid conduit and the fourth conduit is coupled to the divert conduit;
a third three-way valve coupled to a fifth conduit and a sixth conduit, wherein the fifth conduit is coupled to the first process fluid conduit and the sixth conduit is coupled to the divert conduit;
a fourth three-way valve coupled to the second process fluid conduit and the divert conduit; and
a purge gas valve coupled to a seventh conduit, wherein the seventh conduit is coupled to the first process fluid conduit.

15. The apparatus of claim 14, further comprising:
one or more remote plasma sources in fluid communication with the process volume.

16. The apparatus of claim 14, wherein the first three-way valve is coupled to a process fluid source conduit configured to deliver a first process fluid, selected from the group consisting of silane and tetraethoxysilane, to the process volume.

17. The apparatus of claim 16, wherein the second three-way valve is coupled to a second process fluid source conduit configured to deliver a second process fluid, selected from the group consisting of silane and tetraethoxysilane, to the process volume.

18. The apparatus of claim 17, wherein the third three-way valve is coupled to a third process fluid source conduit configured to deliver a third process fluid, selected from the group consisting of oxygen gas and nitrous oxide, to the process volume.

19. The apparatus of claim 18, wherein the fourth three-way valve is coupled to a fourth process fluid source conduit configured to deliver a fourth process fluid, selected from the group consisting of silane and tetraethoxysilane, to the process volume.

20. The apparatus of claim 14, wherein the first process fluid conduit is configured to deliver a first process fluid to an area of the process volume adjacent to a center region of the substrate support, and the second process fluid conduit is configured to deliver a second process fluid to an area of the process volume adjacent to an edge of the substrate support.
